(19) United States
(12) Patent Application Publication
(10) Pub. No.: US 2019/0212741 A1
(43) Pub. Date: Jul. 11, 2019

(54) TRANSMISSION LINE ELECTROMAGNETIC FIELD AND INSTANTANEOUS INSPECTION IMAGE ACQUISITION DEVICE AND METHOD

(71) Applicant: KOREA ELECTRIC POWER CORPORATION, Naju-si (KR)

(72) Inventors: Won-Kyo LEE, Daejeon (KR); Ho-Kwon LEE, Daejeon (KR)

(21) Appl. No.: 16/333,866

(22) PCT Filed: Nov. 8, 2016
(86) PCT No.: PCT/KR2016/012821

§ 371 Date: Mar. 15, 2019

(30) Foreign Application Priority Data
Sep. 21, 2016 (KR) 10-2016-0120787

(51) Int. Cl. G05D 1/00; G01R 29/08; G05D 1/08; B64C 39/02; B64D 47/08; G06T 7/70; H04N 5/232; G08B 7/06; G08B 21/18

(52) U.S. Cl. CPC G05D 1/0094; G01R 29/0878; G05D 1/0816; G01R 29/0892; B64C 39/024; G05D 1/12; G06T 7/70; H04N 5/23299; G08B 7/06; G08B 21/182; B64D 47/08

(57) ABSTRACT

The present invention relates to a transmission line electromagnetic field and instantaneous inspection image acquisition device and method using an unmanned aerial vehicle. The image acquisition device includes: an electromagnetic field measurement unit acquiring an electromagnetic field exposure amount to measure a distance to a subject; an image acquisition unit for photographing with automatic adjustment using information obtained from the electromagnetic field measurement unit; a control unit obtaining image information via an image acquisition camera of the image acquisition unit; and a ground control system, wherein the electromagnetic field exposure amount acquired by the electromagnetic field measurement unit is used to adjust a focus of the image acquisition unit, thereby acquiring a precision image.

### CROSS-REFERENCE TO RELATED APPLICATIONS

This application claims the benefit under 35 U.S.C. Section 371, of PCT International Application No. PCT/KR2016/012821, filed on Nov. 8, 2016, which claimed priority to Korean Patent Application No. KR 10-2016-0120787, filed on Sep. 21, 2016, the disclosures of which are hereby incorporated by the references.

### TECHNICAL FIELD

The present invention relates generally to an unmanned aerial vehicle (UAV), particularly, an unmanned helicopter. More particularly, the present invention relates to an unmanned aerial vehicle-specific transmission line electromagnetic field and instantaneous inspection image acquisition device and method for monitoring a transmission line.

### BACKGROUND ART

An overhead transmission line for large-scale electric power transmission generates an electric field and a magnetic field due to applied voltage and flowing current that are required for electric power transmission. In order to assess an influence on health in terms of long-term exposure to an electromagnetic field and to respond to occurrence of electromagnetic field complaints, it is important to acquire information on distribution of the electromagnetic field around the transmission line. At present, the measurement is conducted manually, so it is difficult to comprehensively measure the electromagnetic field around the overhead transmission line.

An unmanned aerial vehicle (an unmanned helicopter, a drone, and the like) travels with a path, an altitude, and a speed set by an operator, on the basis of the GPS via global and inertial navigation systems, or a control system equipped within the unmanned aerial vehicle is capable of controlling the position, the positioning, the direction and the like. When the unmanned aerial vehicle is equipped with a device for acquiring an electromagnetic field and an image, an electromagnetic field and image acquisition system for transmission line monitoring is configured. Accordingly, it is possible to acquire information on distribution of the electromagnetic field around the transmission line by utilizing spatial mobility of the unmanned aerial vehicle. In general, a precision image acquisition device is composed of an optical lens and has a characteristic called depth of field. When focusing on a subject of which an image is acquired, the focus is given within a particular distance forward and backward of the subject. Here, depth of field is the range in which the image is recognized as being in focus. This depth of field is adjustable by the opening degree of an aperture (a unit adjusting the amount of light that passes through the lens and reaches an image sensor) of the image acquisition device. However, in the case where the aperture opening is small to widen the depth section in which an image is clear, in order to secure the time required for the sufficient amount of light necessary for image acquisition to reach the image sensor, when the time for maintaining the state is long and motion occurs during the time, an image with motion blur is acquired. Therefore, in a device that acquires an image while moving, it is difficult to adjust the depth by adjusting the aperture. Further, depth of field has a characteristic that when the focal distance is short (wide-angle), a depth section in which the image is clear is wide, and when the focal distance is long (telephoto), the depth section in which the image is clear is narrow. In a transmission line monitoring system requiring a long focal distance (telephoto) device for acquiring a precise image, in order to obtain a clear image, it is required to acquire an image by accurately adjusting a focus adjustment position for the depth section in which an image is clear, within a fixed (telephoto) focal distance. Generally, because of this problem, it is difficult to acquire a particular image from an unmanned aerial vehicle. Therefore, in order to acquire a clear image for transmission line monitoring, appropriate focus control is required and thus, remote control is required.

### DISCLOSURE

### Technical Problem

In order to solve the above-described problem, the present invention is intended to propose an unmanned aerial vehicle-specific image acquisition device and method for transmission line monitoring, wherein before inspection of a transmission line and a transmission pylon in a live-line state, a flight path for inspection of an advance desired point is selected, and then an unmanned aerial vehicle automatically flies along a planned flight path; an electromagnetic field measurement sensor unit is utilized to acquire information on distribution of an electromagnetic field around the transmission line; a camera for acquiring a precision image of the transmission line is used for photographing with automatic adjustment using focus adjustment information corrected by information obtained from the electromagnetic field measurement unit, thereby acquiring particular high-resolution transmission line image information.

### Technical Solution

According to the present invention, there is provided a transmission line electromagnetic field and instantaneous inspection image acquisition device using an unmanned aerial vehicle, the device including: an electromagnetic field measurement unit acquiring an electromagnetic field exposure amount to measure a distance to a subject; an image acquisition unit for photographing with automatic adjustment using information obtained from the electromagnetic field measurement unit; a control unit obtaining image information via an image acquisition camera of the image acquisition unit; and a ground control system, wherein the electromagnetic field exposure amount acquired by the electromagnetic field measurement unit is used to adjust a focus of the image acquisition unit, thereby acquiring a precision image.

### Advantageous Effects

According to the present invention of the above-described configuration, observation using an unmanned aerial vehicle without a professional technician aboard is always possible, so that there is an industrial use effect wherein the safety of professional technical personnel is achieved. Further, it is possible to acquire image information of a wide area at lower cost than a manned aircraft in which professional technical personnel, high facility cost, and high maintenance cost are required. As described above, in the transmission line electromagnetic field and instantaneous inspection image acquisition device and in the method of controlling the same according to the present invention, information on distribution of the electromagnetic field around the transmission line is acquired utilizing the spatial mobility of the unmanned aerial vehicle. Therefore, by obtaining the information of distribution of the electromagnetic field around the overhead transmission line, comprehensive measurement of the electromagnetic field is possible. Further, precise focus correction and adjustment are possible using the obtained information on the electromagnetic field.

The electromagnetic field measurement unit is used to accurately and quickly correct and discover the optimum focal distance of the target, and clear image information of a line and a pylon is obtained by the image acquisition camera 210 to which a particular focal distance is input, whereby the problem is accurately distinguished and inspection is easy. Further, a power supply unit 500 composed of a standby generator or a battery is used so that stable operation is possible even in an emergency such as a blackout, and the like. A warning unit 610 makes it possible to visually identify a normal state, a failure state, and the like of the unmanned aerial vehicle. Furthermore, it is possible to acquire information on distribution of the electromagnetic field around the transmission line and a high-precision image required for instantaneous inspection, and it is possible to distinguish the position of the obstacle using distance information, thereby preventing collision of the unmanned aerial vehicle and various obstacles.

### DESCRIPTION OF DRAWINGS

FIG. 1 is a flowchart illustrating an operation according to the present invention.

FIG. 2A and FIG. 2B are diagrams illustrating an overall configuration according to the present invention.

FIG. 3A illustrates an example of setting a target path using a target point.

FIG. 3B illustrates an example of setting an advance flight path shown on a plane.

FIG. 3C to FIG. 3E illustrate examples of setting an advance flight path shown in 3D space.

FIG. 4 illustrates an example of a travel path for acquiring an image of a target point according to the present invention.

FIG. 5 illustrates an example of the exposure amount of the magnetic field depending on a separation distance in the transmission line.

FIG. 6 illustrates an example of the exposure amount of the magnetic field depending on a separation distance in the transmission line using a magnetic field prediction program.

### MODE FOR INVENTION

Hereinbelow, for understanding the invention, preferred embodiments of the present invention will be described in detail with reference to the accompanying drawings. It should be understood that the embodiment of the present invention may be changed to a variety of embodiments and the scope and spirit of the present invention are not limited to the embodiment described hereinbelow. The embodiments of the present invention are provided in order to fully explain the invention for those skilled in the art. Therefore, shapes and sizes of the elements in the drawings may be exaggerated for a more precise description. Wherever possible, the same reference numerals will be used throughout the drawings and the description to refer to the same elements. In the following description of the present invention, a detailed description of known functions and configurations incorporated herein will be omitted when it may make the subject matter of the present invention rather unclear.

The present invention relates to a transmission line electromagnetic field and instantaneous inspection image acquisition device and method using an unmanned aerial vehicle. The image acquisition device includes: an electromagnetic field measurement unit 100 acquiring an electromagnetic field exposure amount to measure a distance to the subject; an image acquisition unit 200 for photographing with automatic adjustment using information obtained from the electromagnetic field measurement unit; a control unit 300 obtaining image information via an image acquisition camera 210 of the image acquisition unit; and a ground control system 700, wherein the electromagnetic field exposure amount obtained by the electromagnetic field measurement unit is used to adjust a focus of the image acquisition unit, thereby acquiring a precision image.

In an operation procedure for inspecting the transmission line to obtain a high-precision image of the transmission line according to the present invention, before flight of an unmanned aerial vehicle system for a field inspection assignment, an inspection plan is made, and data containing the inspection plan is transmitted to the unmanned aerial vehicle and a ground control system. Further, utilizing position information of the wire of the transmission line and a pylon for the inspection, a flight path is selected considering a map and coordinates of an area, position information of a transmission pylon, dangerous area setting, a flight direction, airspeed, and the like for acquiring an electromagnetic field and a high-precision image in such a manner that the unmanned aerial vehicle is designed to perform automatic flight.

The image acquisition unit 200 for the unmanned aerial vehicle is composed of an image acquisition unit and a focus adjustment information deriving unit considering a flight error of an attitude and heading reference system (AHRS), and includes an image acquisition camera 210. The focus information deriving unit may derive the image acquisition camera 210 on the basis of an error between a measurement value of each of roll, pitch, and yaw, and a target value. On the basis of the calculated error, the focus value of the image acquisition camera 210 may be extracted. For example, the control unit 300 may store information on the electromagnetic field exposure amount corresponding to the error in the form of a lookup table. When adjusting the focus of the image acquisition camera 210, distance information is read from this lookup table to control the focus. However, the correction degree of the focus according to the calculated error may vary with the type and the size of the lens that the image acquisition camera uses and with the size of the acquired image, and may be set differently according to user's or designer's intention.

The electromagnetic field measurement unit 100 is composed of an electric field measurement sensor unit 110 and a magnetic field measurement sensor unit 120, and executes acquisition of the electromagnetic field exposure amount to measure the distance to the subject when acquiring an image. For focus adjustment correction of the image acquisition unit 200, a distance to the subject required for adjusting the focus is obtained by the electric field and magnetic field measurement sensor units 110 and 120. Information on the distance to the subject is obtained via the electromagnetic field measurement unit 100, and on the basis of the position of the subject, comparison with the existing focus adjustment value of the focus information deriving unit is performed for correction into an optimum focus adjustment position value.

The image acquisition unit 200 is composed of a monitoring device, such as a high-resolution camera, or the like, requiring focus information. A camera for acquiring a precision image of the transmission line is used for photographing with automatic adjustment using focus adjustment information corrected by the information obtained from the electromagnetic field measurement unit 100, thereby acquiring particular high-resolution transmission line image information.

The exemplary embodiments of the present invention will be described in detail with reference to the accompanying drawings such that the present invention can be easily embodied by those skilled in the art to which this present invention belongs.

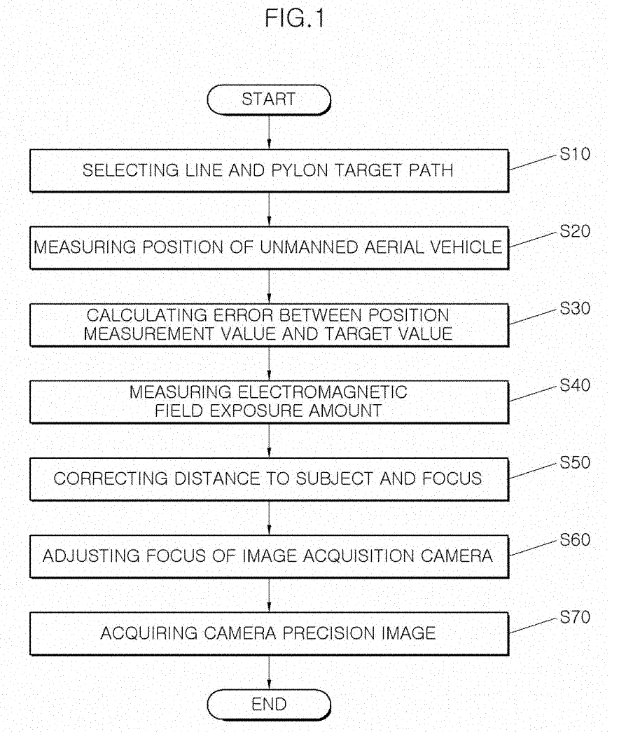

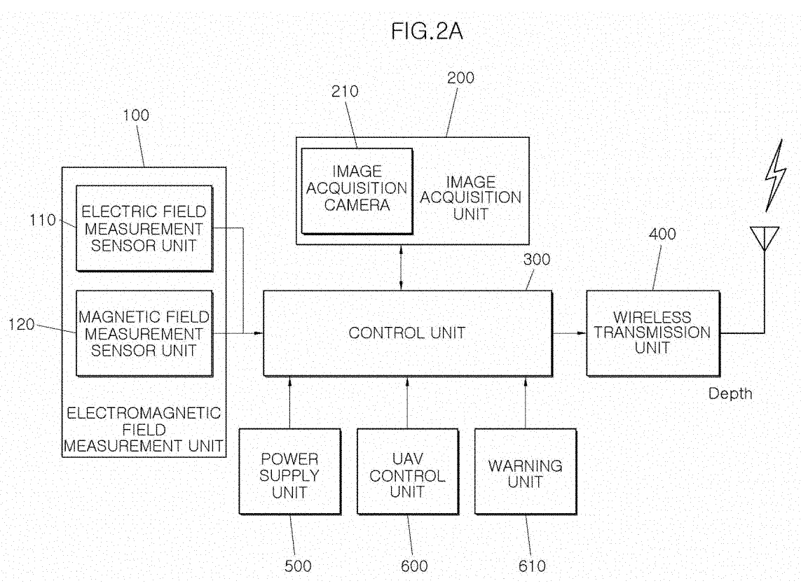

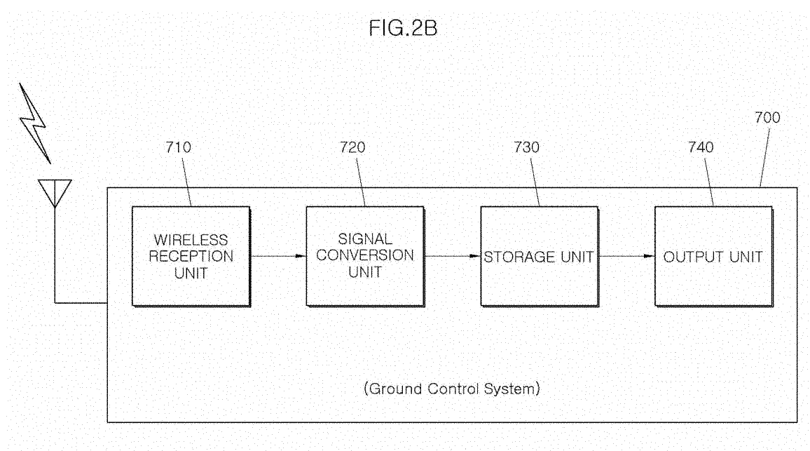

FIG. 1 illustrates a flowchart of an operation of the present invention. FIG. 2A and FIG. 2B illustrate diagrams of an overall configuration.

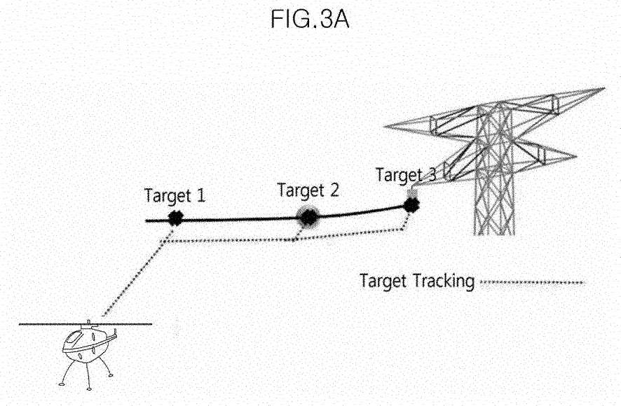

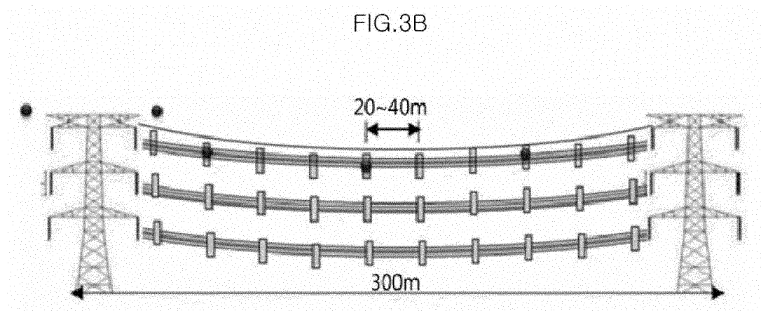

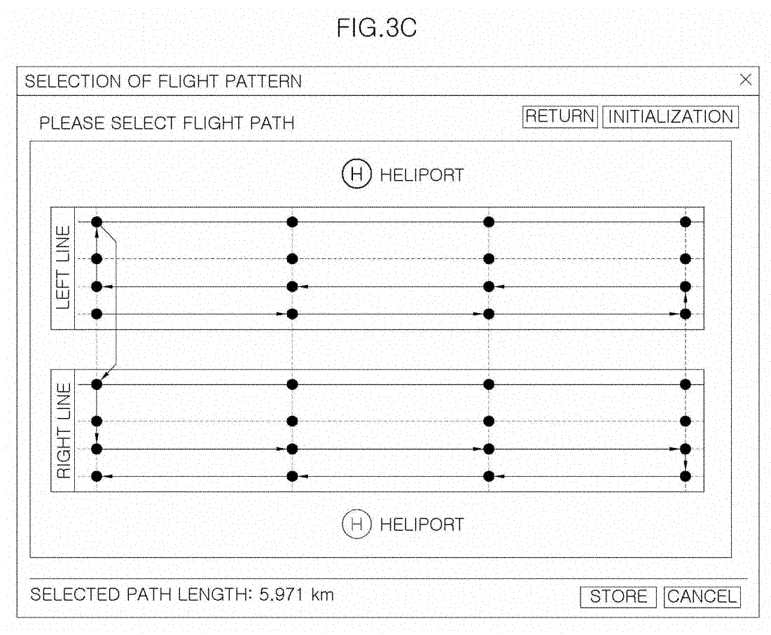

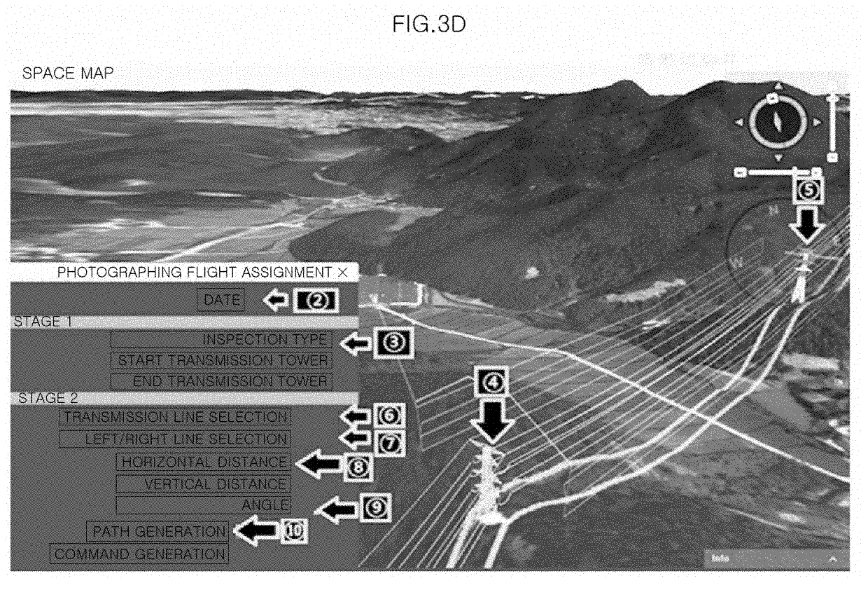

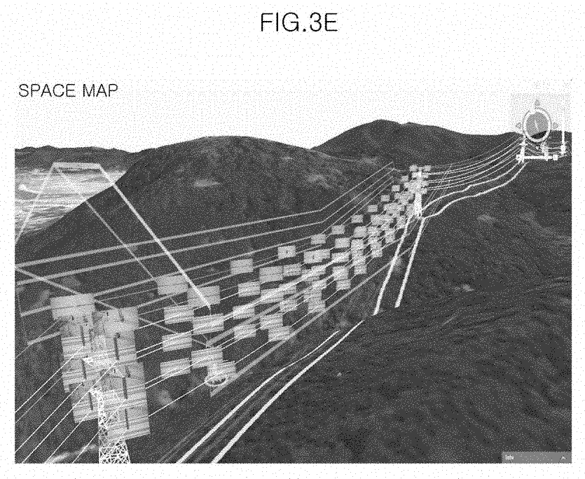

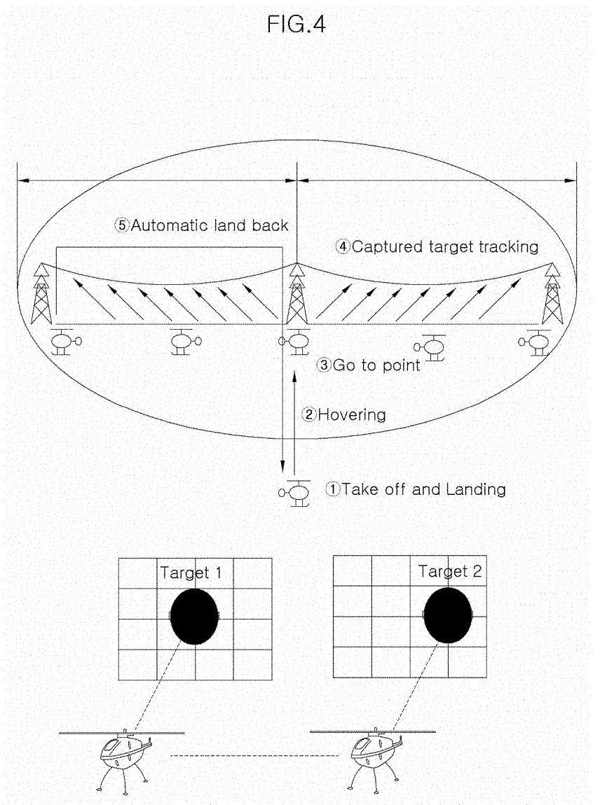

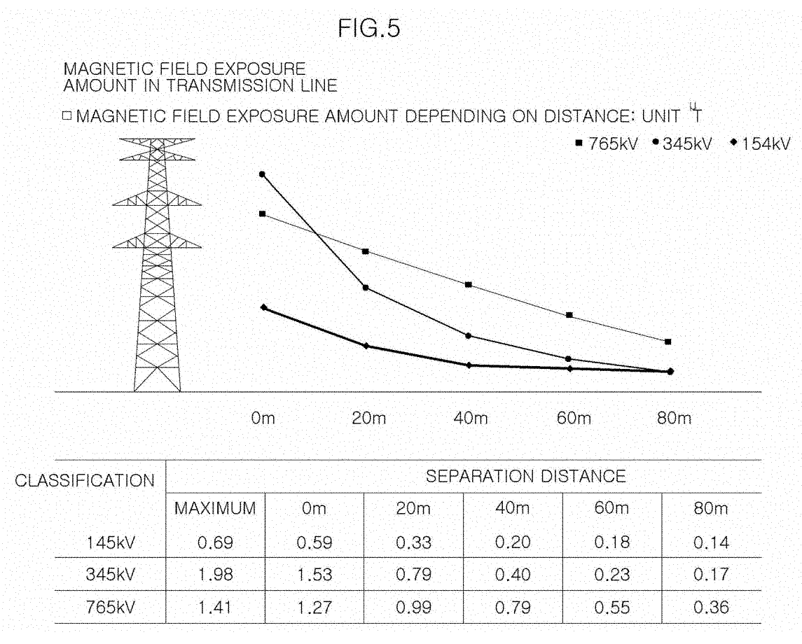

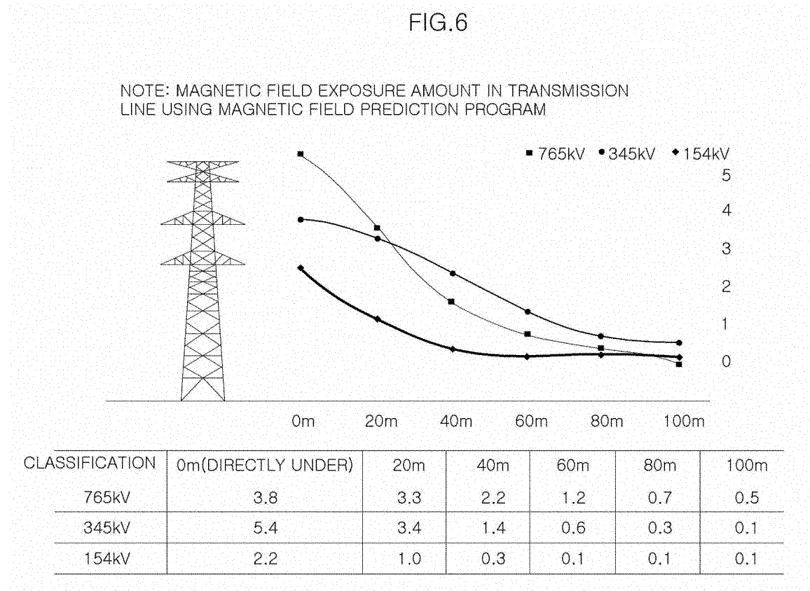

FIG. 3A to 3E illustrate methods of selecting a target path of a transmission line and a pylon device. FIG. 4 illustrates an example of a travel path for a target point. FIG. 5 illustrates an example of the exposure amount of the magnetic field depending on a separation distance in the transmission line. FIG. 6 illustrates an example of the exposure amount of the magnetic field depending on a separation distance using a magnetic field prediction program.

The operation procedure will be described with reference to FIG. 1.

In order to obtain a high-precision image of an overhead transmission line, with procedures for deriving inspection items using the unmanned aerial vehicle, for a detailed inspection reference of each inspection-possible item and enhancement of efficiency of a precision image of the transmission line, for automatic flight performance after inputting a map and coordinates of an area, position information of the transmission pylon, dangerous area setting, a flight direction, and airspeed to perform an advance inspection assignment, and for a flight path, a risk factor, a safety distance, a precision inspection section, and the like, a 2D/3D-based target point is examined, whereby an inspection flight path for acquiring an electromagnetic field and an image is set at step S10. Next, roll, pitch, and yaw values, which are output values of the attitude and heading reference system (AHRS) equipped within the unmanned aerial vehicle, are converted for measurement into 3D position (X, Y, and Z axes) information of the unmanned aerial vehicle at step S20. A path error value according to the actual travel in comparison with advance travel path target reference position (X, Y, and Z axes) values of the unmanned aerial vehicle is calculated at step S30. Next, the electromagnetic field measurement unit 100 measures the exposure amount of the electric field and of the magnetic field at step S40. The electric field and magnetic field exposure amount obtained by the electromagnetic field measurement unit is detected to calculate distance information of the subject, such as a transmission line, a pylon, or the like, and by comparing the two values, the focus information is corrected at step S50. The corrected focus adjustment information is used to acquire image information by the image acquisition camera 210 at step S70.

Output information of the attitude and heading reference system (AHRS) of the unmanned aerial vehicle is used to clarify a magnetic field measurement position that is planned in advance and an image acquisition target. As the result of performing focus adjustment correction on the basis of the result of measuring the electromagnetic field, the optimum focus adjustment position is discovered and the information is used to control the image acquisition camera 210, thereby obtaining a transmission line electromagnetic field and a high-resolution image for instantaneous inspection so as to accurately monitor the transmission line.

Referring to FIG. 2A and FIG. 2B, the image acquisition unit 200 is composed of the image acquisition camera 210 and obtains image information using the same. The control unit 300 performs focus adjustment correction on the basis of the result information input from the electromagnetic field measurement unit 100 and commands the image acquisition camera 210 so as to obtain image information.

Further, utilizing the result input to the electromagnetic field measurement unit 100, when there is no electromagnetic field measurement value (when there is no transmission line information data), the control unit 300 controls a built-in light (an LED, and the like) and sound equipment (a standby warning sound) of the unmanned aerial vehicle to change a warning sound and a danger notification light in such a manner that supplementation is possible by manually operating camera control (focal distance adjustment) and aerial vehicle position control. A warning (notification) signal is transmitted from the unmanned aerial vehicle ground control system 700 via the wireless transmission unit 400. The wireless transmission unit 400 receives the signal generated by the control unit 300 and transmits the signal through an antenna.

The power supply unit 500 supplies power to the control unit 300. Here, the power is also supplied to the units, the electromagnetic field measurement unit 100, the image acquisition unit 200, the wireless transmission unit 400, a flying vehicle 600, and the warning unit 610, that are connected to the control unit 300. The power supply unit 500 supplying power to the device of the present invention receives ordinary power such as 220 V AC (60 Hz) and converts the same into power required by the device of the present invention for supply. A standby generator, a battery, or an uninterruptible power supply (UPS) is provided to supply power to the device of the present invention even in an emergency such as a blackout or natural disaster.

It is desired that the warning unit 610 is configured to include a warning light and a warning sound. The warning unit 610 is connected to the control unit 300, and the control unit 300 controls whether to turn on the light or controls the color of the light. The warning light makes it possible to visually identify a normal state, a failure state, and the like of the unmanned aerial vehicle of the present invention.

A wireless reception unit 710 receives a data signal from the wireless transmission unit 400 in a wireless manner and provides the result to a signal conversion unit 720. The signal conversion unit 720 converts the data signal provided from the wireless reception unit 710 into a current signal and provides the result to a storage unit 730. The storage unit 730 outputs the stored data via an output unit 740. The output unit 740 may be a display device or a warning generating device informing the user of observation information. The output unit 740 may include an external device, such as a computer, and the like, and an input/output interface. The result stored in the storage unit 730 may be processed by the user later for use in an observation system, and the like.

FIG. 3A to FIG. 3E illustrate, before inspection of the transmission line and the transmission pylon in a live-line state by the unmanned aerial vehicle,

a method of selecting a flight path for inspection of an advance desired point. As shown in FIG. 3A, for inspection of the transmission line, it is necessary to select a target point and a flight path. The target point is selected as position information of the transmission line, the pylon, an aircraft warning light, and an insulator device, and it is possible to acquire the electromagnetic field and a high-resolution image for inspection. FIG. 3B illustrates an example of selecting an advance flight path shown on a plane. Here, the point represents the target point (flight path) between the pylon and the pylon on the transmission line, wherein the unmanned aerial vehicle travels and acquires an image of the target point. FIG. 3C to FIG. 3E illustrate examples of different target points that are generated by being extracted from a virtual 3D modeling space on the basis of the actual positions of the transmission line and the transmission pylon. Representation of information with 3D modeling enables more stereoscopic inspection flight path setting and management of data. Also, an intuitive flight path may be checked. Data of a point selected from 3D information on points on the actual transmission line is compared with the actually stored data so that an efficient analysis is possible, resulting in acquisition of a more precise image.

FIG. 4 illustrates an example of a travel path for acquiring an image of the target point. It illustrates the travel path where the unmanned aerial vehicle acquires an image of a target point and an image of another target point.

FIG. 5 illustrates the exposure amount of the magnetic field of the transmission line. In the transmission line, the exposure amount of the magnetic field depending on a distance

is checked. On the basis of the exposure amount of the electromagnetic field measured by the electromagnetic field sensor unit of the unmanned aerial vehicle, a separation distance to the subject is determined.

Referring to FIG. 2A and FIG. 2B, in the method of controlling the unmanned aerial vehicle for transmission line monitoring according to the present invention, various image acquisition devices (CCD, CMOS, IR (thermographic), UV (corona) cameras, and the like) may be used for reinforcement depending on the required functions.

The embodiments of the present invention have been described for illustrative purposes, and those skilled in the art to which the present invention pertains will easily understand that the present invention may be modified in various ways and that other equivalent embodiments are possible. Accordingly, it will be understood that the present invention is not limited to the embodiment described in the detailed description. Accordingly, the true range of protection of the present invention should be determined by the technical spirit of the following claims. Furthermore, it should be understood that the present invention includes all of changes, equivalents and substitutes without departing from the spirit and range of right of the present invention defined by the appended claims.

1. A transmission line electromagnetic field and instantaneous inspection image acquisition device using an unmanned aerial vehicle, the device comprising:
an electromagnetic field measurement unit acquiring an electromagnetic field exposure amount to measure a distance to a subject;
an image acquisition unit for photographing with automatic adjustment using information obtained from the electromagnetic field measurement unit;
a control unit obtaining image information via an image acquisition camera of the image acquisition unit; and
a ground control system,
wherein the electromagnetic field exposure amount acquired by the electromagnetic field measurement unit is used to adjust a focus of the image acquisition unit, thereby acquiring a precision image.

2. The device of claim 1, wherein the electromagnetic field measurement unit comprises an electric field measurement sensor unit and a magnetic field measurement sensor unit, and
a measurement value of the electromagnetic field measurement unit is used for correction into an optimum focus adjustment position value.

3. The device of claim 1, wherein the image acquisition unit comprises the image acquisition camera, and
the image information is obtained via the image acquisition camera.

4. The device of claim 1, wherein the control unit performs focus correction using result information input from the electromagnetic field measurement unit, and then acquires the image information by commanding the image acquisition camera.

5. The device of claim 4, wherein the control unit controls, when there is no input value from the electromagnetic field measurement unit, a warning sound and a danger notification light to be changed,
controls a wireless transmission unit to receive a signal generated by the control unit and to transmit the signal to a wireless reception unit of the ground control system, and
controls an output unit of the ground control system to output a warning signal.

6. The device of claim 5, wherein the ground control system comprises:
the wireless reception unit receiving data via the wireless transmission unit;
a signal conversion unit converting data of the wireless reception unit into a current signal;
a storage unit storing a signal received from the signal conversion unit; and
the output unit informing a user of the signal,
wherein the output unit is a display and a warning generating device.

7. A transmission line electromagnetic field and instantaneous inspection image acquisition method using an unmanned aerial vehicle, the method comprising:
setting a target path;
measuring a position of the unmanned aerial vehicle;
calculating an error and measuring an electromagnetic field exposure amount;
correcting a distance to a subject and a focus;
adjusting a focus of an image acquisition camera; and
acquiring an camera precision image,
wherein a precision image is acquired while automatically flying along the set target path according to planned order.

8. The method of claim 7, wherein the target path includes a target point based on a transmission pylon position, a target point based on a transmission line middle position, and a target point based on a transmission pylon device, and
setting of the flight path and data management are performed in a virtual 3D modeling space based on an actual position.

9. The method of claim 8, wherein the target point based on the transmission pylon position is a point for acquiring an electromagnetic field generated on the basis of a position of a pylon of a transmission line, and an image thereof,
the target point based on the transmission line middle position is a point for acquiring an electromagnetic field generated on the basis of a wire of the transmission line, and an image thereof, and
the target point based on the transmission pylon device is a point for acquiring an electromagnetic field generated on the basis of the transmission pylon device, and an image thereof.

10. The method of claim 7, wherein at the calculating of the error, values output from an attitude and heading reference system equipped with the unmanned aerial vehicle are converted into 3D position information for calculating a path error depending on a target value and on actual travel.

11. The method of claim 10, wherein the values output from the attitude and heading reference system are roll, pitch, and yaw values, and
values that result from the conversion into the 3D position information are a value representing the roll value in an X axis, a value representing the pitch value in a Y axis, and a value representing the yaw value in a Z axis.

12. The method of claim 7, wherein at the correcting of the distance to the subject and the focus, the calculated error and the measured exposure amount are compared such that information on the distance to the subject is calculated and the focus is corrected.

13. The method of claim 12, wherein the distance to the subject is determined from the electromagnetic field exposure amount measured by an electromagnetic field sensor unit of the unmanned aerial vehicle.
